(19) United States
(12) Patent Application Publication
(10) Pub. No.: US 2009/0174071 A1
(43) Pub. Date: Jul. 9, 2009

(54) Semiconductor device including electrically conductive bump and method of manufacturing the same

(75) Inventors: Clinton Chao, Hsinchu (TW); Pei-Haw Tsao, Tai-chung (TW); Szu Wei Lu, Hsinchu City (TW); Tjandra Winata Karta, Hsinchu (TW)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Taiwan Semiconductor Manufacturing Company, Ltd.,

(21) Appl. No.: 12/379,921

(22) Filed: Mar. 4, 2009

Related U.S. Application Data
(62) Division of application No. 11/437,726, filed on May 22, 2006.

(51) Int. Cl. H01L 23/48; H01L 21/768

(52) U.S. Cl. 257/737; 438/613; 257/E23.068; 257/E21.575

(57) ABSTRACT

A semiconductor device and method of manufacturing are provided that include forming an electrically conductive bump on a substrate and forming at least one passivation layer on the bump to reduce solder joint failures.

### TECHNICAL FIELD

The present invention generally relates to a semiconductor device and a method of making a semiconductor device. More particularly, this invention relates to semiconductor devices including electrically conductive bumps and methods for manufacturing such devices.

### DESCRIPTION OF THE RELATED ART

In the semiconductor industry, there are several known ways for packaging semiconductor devices. Such packaging typically requires making electrical connections between an integrated circuit (IC) chip and a package or module structure. Such connections between the IC and its package or module may be made using a wire, tape automated, or flip chip bonding. In flip chip bonding, the IC is directly bonded to electrical connection pads on a substrate in a face down (that is “flipped”) orientation. Examples of substrates include ceramic substrates, circuit boards, or chip carriers.

Typically, ICs that are flip chip bonded are subjected to a process called bumping in which electrically conductive bumps, e.g., solder bumps, are formed on the IC. Bumping is typically performed at the wafer level. Each bump makes electrical contact with circuitry within the IC. When bonded to the substrate, each bump also makes electrical contact with one of the connection pads on the substrate. The substrate includes connection pins, e.g., on its side opposite the side with the connection pads, for making connections to the IC via the substrate.

The bumps on the flip chip assembly serve several functions. The bumps provide an electrically conductive path from the IC chip (e.g. die) to the substrate on which the IC is mounted. A thermally conductive path is also provided by each bump to carry heat from the chip to the substrate. The bumps also provide part of the mechanical mounting of the IC to the substrate. A spacer is provided by the bumps that prevents electrical contact between the IC and the substrate connectors. Finally, the bumps act as a short lead to relieve mechanical strain between the chip and the substrate.

Flip chips are typically made by a process including placing solder bumps on the silicon wafer. The solder bump flip chip processing typically includes four major sequential steps in which the ICs that will be flip chip bonded are being formed: 1) processing an under-bump metallization (UBM) on the wafer for solder bumps to be deposited on, and 2) forming or reflowing the solder deposit to form the solder bumps on the wafer's UBMs. Then, after individual ICs are diced from the wafer, the remaining two steps are performed: 3) attaching the solder bumped die to a board, substrate or carrier; and 4) assuring the assembly reliability by filling the IC-to-substrate partial spacing with a certain epoxy underfill.

The first step in a typical solder bumping process involves preparing the semiconductor wafer bumping sites on bond pads of the individual ICs defined in the semiconductor wafer. The preparation may include cleaning, removing insulating oxides, and preparing a pad metallurgy that will protect the ICs while making good mechanical and electrical contact with the solder bump. Accordingly, protective metallurgy layers may be provided over the bond pad. Examples of such metallurgy include a UBM, which generally consists of successive layers of metal. These layers may include an “adhesion” layer that adheres well to both the bond pad metal and a surrounding passivation layer, and provides a strong, low-stress, mechanical and electrical connection. A “diffusion barrier” layer prevents the diffusion of solder into the underlying material. A “solder wetting” layer provides a wettable surface for the molten solder during the solder bumping process, for good bonding of the solder to the underlying metal.

A variety of known UBM structures accomplish the above functions and have two or three layers. For solder-based bumps, for example, known UBM structures include layers of Cr—Cu—Au, Cr—NiV—Au, Ti—Cu, TiW—Cu, or Ti—Ni. The UBM layers may be deposited by electro-less plating, sputtering, and/or electrolytic plating. Solder bumps may be typically formed of lead (Pb) and tin (Sn) alloys or alloys of Sn. Two widely used methods of depositing solder now are electroplating and stencil-printing.

In manufacturing processes in which the IC chip is bonded to the substrate within a short time after bump fabrication, there is typically no problem of oxidation on the bumps. More commonly, however, the IC wafer needs to be tested and stored for a period of time before being diced and bonded to the substrate via the bumps. Between the time the IC wafer is bumped and the time it is bonded to the substrate, the lead-tin solder bumps may become heavily oxidized by exposure to normal atmospheric conditions. The oxidation process continues and penetrates into the lead-tin solder material rather than stopping at the surface thereof. In this situation, when the IC chip is subsequently bonded to the substrate, the powdery lead oxide could result in unreliable solder joints, referred to as “cold joints.”

Therefore, before bonding of the IC chip to the substrate via the bumps, any oxide needs to be removed from the bumps by an etching-cleaning-fluxing process. This process can be costly. If bonding of the IC chip to the substrate is delayed after the oxide removal process, oxide may reform and the oxide removal process needs to be repeated. Each time the oxide removal process is performed, the solderable layer of the UBM may be depleted more because of formation of an intermetallic compound at the solder bump-UBM interface.

Alternatively, the semiconductor device may be stored in an inert environment, such as in a nitrogen desiccator or in a vacuum environment. However, a completely oxygen-free environment cannot be guaranteed and oxidation can still occur.

The present invention is directed to overcome one or more of the problems of the related art.

### SUMMARY OF THE INVENTION

In accordance with the purpose of the invention as embodied and broadly described, there is provided a method of manufacturing a semiconductor device, comprising: providing a substrate including a bonding pad; forming an electrically conductive bump on the bonding pad; and forming at least one passivation layer on the bump, so that the bump is covered by at least one passivation layer.

In accordance with the present invention, there is also provided a semiconductor device, comprising: a substrate including a bonding pad; an electrically conductive bump on the bonding pad; and at least one passivation layer formed on the bump, so that the bump is covered by the at least one passivation layer.

Additional features and advantages of the invention will be set forth in the description that follows, being apparent from the description or learned by practice of the invention. The features and other advantages of the invention will be realized and attained by the semiconductor device structures and methods of manufacture particularly pointed out in the written description and claims, as well as the appended drawings.

It is to be understood that both the foregoing general description and the following detailed description are exemplary and explanatory, and are intended to provide further explanation of the invention as claimed.

### BRIEF DESCRIPTION OF THE DRAWINGS

The accompanying drawings, which are incorporated in and constitute a part of this specification, illustrate embodiments of the invention and, together with the description, serve to explain the features, advantages, and principles of the invention.

In the drawings:

FIG. 1 illustrates a solder bump with an over-bump passivation layer, consistent with embodiments of the present invention.

### DESCRIPTION OF THE EMBODIMENTS

Reference will now be made in detail to embodiments of the present invention, examples of which are illustrated in the accompanying drawings. Wherever possible, the same or similar reference numbers will be used throughout the drawings to refer to the same or like parts.

Embodiments consistent with the present invention provide for a method of manufacturing a semiconductor device, including a solder bump with an over-bump passivation layer for protecting the bump from oxidation before bonding of the semiconductor device to the substrate, and for preventing the solder cold joint phenomenon.

To solve problems associated with the approaches in the related art discussed above and consistent with an aspect of the present invention, a semiconductor device and its method of manufacture will next be described.

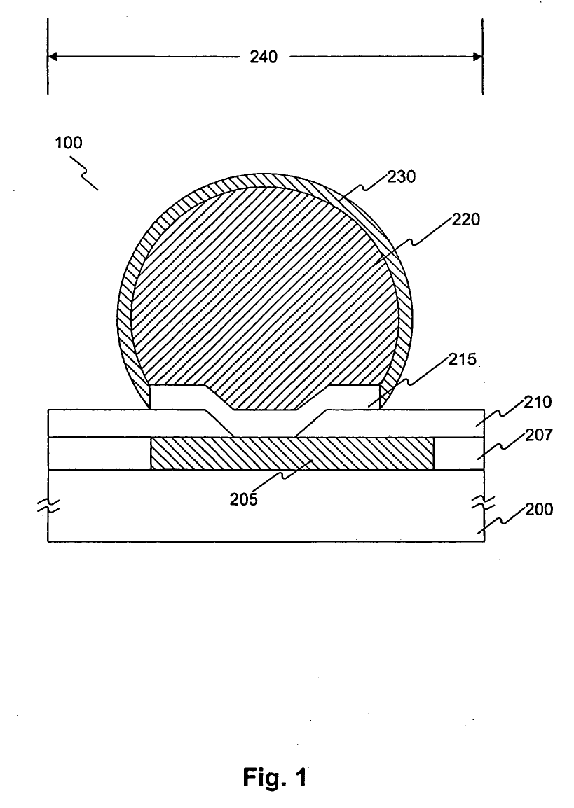

FIG. 1 illustrates a semiconductor device 100 with an electrically conductive bump on a substrate according to an embodiment consistent with the present invention. In FIG. 1, the semiconductor device 100 includes a substrate 200 with a plurality of alternating metallization and dielectric layers. A bond pad 205 is provided on a metal interconnection layer 207 on the substrate 200 and connects to the integrated circuitry, not shown, within the semiconductor device 100. An under-bump passivation layer 210 is provided on the metal interconnection layer 207 on the substrate 200 and bond pad 205, and includes an opening exposing a portion of the bond pad 205. A UBM 215 is provided over the under-bump passivation layer 210 and into the opening formed in the under-bump passivation layer 210 and is in contact with the bond pad 205. Formation of the bond pad 205, under-bump passivation layer 210, UBM 215 may be accomplished by conventional means.

An electrically conductive bump material 220, such as a solder material including Pb (or any other suitable bumping material) may be deposited over the UBM 215 by conventional means. Preferably, the electrically conductive bump material 220 is solder in any suitable composition including, for example, a known composition of 3-5 weight % (w/o) Sn and 97-95 weight % (w/o) Pb. The electrically conductive bump material 220 may be deposited, for example, by any of a variety of methods including electroplating, screen or stencil printing, evaporation, jet printing thermomechanical/pressure through nozzle, by means of electromechanical/piezoelectric device, magneto-fluidynamic or electromagneto-fluidynamic devices, micro-punching or any other known method.

As with conventional bump forming methods, the electrically conductive bump material 220 may be oxidized if left exposed to air. In the case of a solder bump for the electrically conductive bump material 220, for example, lead oxide (PbO₂) may form upon exposure to air for even short periods of time. The presence of an oxide on the electrically conductive bump material 220 can lead to the undesirable solder cold joint phenomenon discussed previously.

In order to eliminate solder cold joints and repeated oxide formation on the electrically conductive bump material 220, the inventors have devised an improved solder bump by providing an over-bump passivation layer 230 for protecting the electrically conductive bump material 220 from oxidation before subsequent device processing steps, such as flip-chip bonding. The over-bump passivation layer 230 is formed by selectively covering the electrically conductive bump material 220 with an inert and dissolvable metal, such as gold (Au), or an organic material, such as an organic solderability preservative (OSP). Gold easily diffuses into solder bumps, such as the electrically conductive bump material 220, when the bump material 220 is melted for bonding. An OSP readily evaporates upon melting the solder bumps in subsequent processing steps. In either case, the over-bump passivation layer 230, formed by gold or OSP, will not adversely affect later solderability of the bump material 220. Alternatively, deposition of a separate layer of tin as the over-bump passivation layer over bump material 220 is contemplated, since an oxide of tin formed on the surface of the bump material 220 may act as a protective layer, impeding further oxidation into the bulk of bump material 220 once surface passivation occurs.

If an inert metal is used as the over-bump passivation layer 230, it is selectively coated only on the bump material 220 because the conductivity of the inert metal could otherwise adversely affect device operation if deposited on areas other than on the bump material 220. In FIG. 1, a region 240 of selective coating over the bump material 220 is indicated between the arrows. Gold or tin may be selectively coated by immersing the device 100 including the bump material 220 in a plating solution containing an inert metal, such as gold (or, optionally, non-inert tin), causing coating formation by an electro-less process. The bump material 220, containing lead, for example, is self-activated so that a catalyst is not needed for the electro-less coating process. The selective coating process can thus be used to coat gold (or, optionally, deposit tin) only on the bump material 220 and not anywhere else. Presumably, selective oxidation of tin may be achieved by a chemical vapor process as an alternative. However, flux must be applied to remove the tin oxide for a subsequent bonding processing since stannous or stannic oxide does not dissolve in a lead-containing solder.

Alternatively, as noted above, the layer 230 can be provided as an organic material, such as OSP (a liquid, insulating, material), which can be spun or sprayed on the semiconductor device 100, or the semiconductor device 100 may be dipped in a solution of OSP. The semiconductor device 100 is then baked so that the solvent in the OSP is driven out, leaving behind an OSP-based over-bump passivation layer.

Thus, embodiments consistent with the present invention provide a solder bump with an over-bump passivation layer for protecting the bump from oxidation before bonding of the IC chip to the substrate, and for preventing the solder cold joint phenomenon. Embodiments consistent with the invention may also permit prolonged shelf-life of semiconductor devices with bumps, independent of the storage environment used. Further, embodiments consistent with the present invention which utilize gold or OSP as the over-bump passivation layer, may eliminate the need to apply solder flux normally during the flip chip assembly process, an otherwise essential step, since oxidation has already been prevented by the gold or OSP passivation. OSP also acts as a flux when melting of solder takes place upon bonding.

It will be apparent to those skilled in the art that various modifications and variations can be made in the disclosed structures and methods without departing from the scope or spirit of the invention. Other embodiments of the invention will be apparent to those skilled in the art from consideration of the specification and practice of the invention disclosed herein. It is intended that the specification and examples be considered exemplary only, with a true scope and spirit of the invention being indicated by the following claims.

1.-18. (canceled)

19. A method of manufacturing a semiconductor device, comprising:
providing a substrate including a bonding pad;
forming an electrically conductive bump on the bonding pad; and
forming at least one passivation layer on the bump, so that the bump is covered by the at least one passivation layer, wherein the at least one passivation layer is formed by spinning, dipping, or spraying the substrate and bump with an organic solderability preservative.

20. The method of manufacturing a semiconductor device according to claim 19, wherein an under-bump metallization is formed on the bonding pad.

21. The method of manufacturing a semiconductor device according to claim 19, wherein the electrically conductive bump is formed from at least one of Au, Cu, Al, and Ni.

22. The method of manufacturing a semiconductor device according to claim 19, wherein the electrically conductive bump is formed from a Pb—Sn solder.

23. A method of manufacturing a semiconductor device, comprising:
providing a substrate including a bonding pad;
forming an electrically conductive bump on the bonding pad; and
forming at least one passivation layer on the bump, so that the bump is covered by the at least one passivation layer, wherein the at least one passivation layer is formed by depositing tin (Sn) on the bump.

24. The method of manufacturing a semiconductor device according to claim 23, wherein an under-bump metallization is formed on the bonding pad.

25. The method of manufacturing a semiconductor device according to claim 23, wherein the electrically conductive bump is formed from at least one of Au, Cu, Al, and Ni.

26. The method of manufacturing a semiconductor device according to claim 23, wherein the electrically conductive bump is formed from a Pb—Sn solder.

27. A semiconductor device, comprising:
a substrate including a bonding pad;
an electrically conductive bump formed on the bonding pad; and
at least one passivation layer formed on the bump, so that the bump is covered by the at least one passivation layer, wherein the at least one passivation layer comprises an organic solderability preservative.

28. The semiconductor device according to claim 27, further comprising an under-bump metallization formed on the bonding pad.

29. The semiconductor device according to claim 27, wherein the electrically conductive bump comprises at least one of Au, Cu, Al, and Ni.

30. The semiconductor device according to claim 27, wherein the electrically conductive bump comprises a Pb—Sn solder.

31. A semiconductor device, comprising:
a substrate including a bonding pad;
an electrically conductive bump formed on the bonding pad; and
at least one passivation layer formed on the bump, so that the bump is covered by the at least one passivation layer, wherein the at least one passivation layer comprises tin (Sn).

32. The semiconductor device according to claim 31, further comprising an under-bump metallization formed on the bonding pad.

33. The semiconductor device according to claim 31, wherein the electrically conductive bump comprises at least one of Au, Cu, Al, and Ni.

34. The semiconductor device according to claim 31, wherein the electrically conductive bump comprises a Pb—Sn solder.
